(19) United States
(12) Patent Application Publication
(10) Pub. No.: US 2010/0207163 A1
(43) Pub. Date: Aug. 19, 2010

(54) SEMICONDUCTOR DEVICE INCLUDING ELECTROSTATIC-DISCHARGE PROTECTION CIRCUIT

(75) Inventors: Hiroaki YABU, Kyoto (JP); Katsuya Arai, Kyoto (JP); Toshihiro Kougami, Kyoto (JP)

Correspondence Address: MCDERMOTT WILL & EMERY LLP, 600 13TH STREET, NW, WASHINGTON, DC, 20005-3096, US

(73) Assignee: PANASONIC CORPORATION, Osaka (JP)

(21) Appl. No.: 12/771,585

(22) Filed: Apr. 30, 2010

Related U.S. Application Data
(63) Continuation of application No. PCT/JP2009/003247, filed on Jul. 10, 2009.

(30) Foreign Application Priority Data
Sep. 11, 2008 (JP) 2008-233678

(51) Int. Cl. H01L 23/60

(52) U.S. Cl. 257/173; 361/56; 257/E23.153

(57) ABSTRACT

A semiconductor device includes a protected circuit and an electrostatic-discharge protection circuit. The electrostatic-discharge protection circuit includes a first well of a first conductivity type and a second well of a second conductivity type formed in contact with each other in a semiconductor substrate, a first impurity diffusion layer of the first conductivity type and a third impurity diffusion layer of the second conductivity type formed apart from each other in the first well, and a second impurity diffusion layer of the second conductivity type and a fourth impurity diffusion layer of the first conductivity type formed apart from each other in the second well. The second and the third impurity diffusion layers are formed adjacent to each other interposing an element isolation region provided across a border between the first and the second wells.

### CROSS-REFERENCE TO RELATED APPLICATION

This is a continuation of PCT International Application PCT/JP2009/003247 filed on Jul. 10, 2009, which claims priority to Japanese Patent Application No. 2008-233678 filed on Sep. 11, 2008. The disclosures of these applications including the specifications, the drawings, and the claims are hereby incorporated by reference in its entirety.

### BACKGROUND

The present disclosure relates to semiconductor devices including electrostatic-discharge protection circuits which protect protected circuits from electrostatic discharges.

In recent years, the integration level has been increasing in semiconductor devices as elements become smaller in size and higher in density. As the integration level is increased, the tolerance for electrostatic discharges (referred to hereinafter as “surges”) of a semiconductor device is decreasing. For example, there is an increased probability that an element, such as an input circuit, an output circuit, and an internal circuit, is destructed, or that the performance of an element is reduced by a surge propagating from a terminal for external connection. Accordingly, a semiconductor device includes an electrostatic discharge (ESD) protection circuit connected to a terminal for external connection in order to protect from surge an input circuit, an output circuit, an input/output circuit, or an internal circuit.

High discharge capability is demanded from an ESD protection circuit. Thus, it is required that a current capability on the order of amperes be provided for a surge applied for not more than several hundreds nanoseconds, and low-impedance operation be possible. Meanwhile, from a viewpoint of manufacturing cost, it is demanded that the occupied area of an ESD protection circuit be small. As an ESD protection circuit capable of meeting these demands and of providing a high electrostatic-discharge resistance (ESD resistance) for a semiconductor device, an ESD protection circuit of a thyristor (silicon-controlled rectifier: SCR) type is utilized. (see, e.g., Patent Document 1.)

As shown in FIG. 13, a conventional ESD protection circuit of an SCR type is configured such that a p-type semiconductor layer 144 is formed over a substrate, and an n-type well 146 is formed in the p-type semiconductor layer 144. An n⁺ region 150 and a p⁺ region 148 are formed in the n-type well 146. An n⁺ region 152 and a p⁺ region 154 are formed in the p-type semiconductor layer 144. The p⁺ region 148 is connected to a pad 112, and the n⁺ region 150 is connected to the pad 112 so as to provide a resistive connection between the pad 112 and the n-type well 146. The n⁺ region 152 and the p⁺ region 154 are grounded. The p⁺ region 154 is connected to a resistive component provided by the p-type semiconductor layer 144.

If a surge is applied from the pad 112, a parasitic NPN transistor of the SCR breaks down. This causes a current to flow into the base of the parasitic NPN transistor, thereby conducting electricity between the collector and the emitter. As a result, the collector current of the parasitic NPN transistor, in turn, becomes the base current of a parasitic PNP transistor, thereby placing the parasitic PNP transistor into an “on” state. A positive feedback to increase the conductivity of the parasitic NPN transistor is created by placing the parasitic PNP transistor into an “on” state. Thus, a low-impedance discharge path is established between the pad 112 and the ground, which is kept until the voltage falls to or below a hold voltage of the SCR. As a result, the surge current is conducted to ground, and thus the internal circuit can be protected.
Patent Document 1: Japanese Examined Patent Application Publication No. H05-065061

### SUMMARY

However, a conventional ESD protection circuit of an SCR type has a problem in that the hold voltage of the SCR is very low. If the hold voltage of the SCR is lower than a normal operation voltage of the semiconductor device, latch-up occurs during a normal operation. If latch-up occurs, a high current continues to flow between the power supply and the ground, thereby causing destruction thereof due to overcurrent.

In order to improve the latch-up tolerance, the hold voltage of the SCR needs to be higher than the normal operation voltage. One method to increase the hold voltage of the SCR may be to reduce a current amplification factor of a parasitic transistor by increasing the spacing between the anode and the cathode of the SCR. However, increasing the spacing between the anode and the cathode of the SCR causes the occupied area of the SCR to increase. In addition, this also creates problems of decrease of current capability and increase of impedance.

Another method to increase the hold voltage of the SCR may be to increase the area of the p⁺ region formed in the p-type layer. Increasing the area of the p⁺ region causes the base resistance of the parasitic NPN transistor to decrease, and thus the hold voltage is expected to increase. However, also in this case, the occupied area of the SCR increases.

It is an object of the present disclosure to solve the above problems, and achieve a semiconductor device including an electrostatic-discharge protection circuit having a high latch-up tolerance and a small occupied area.

In order to achieve the above object, the present disclosure provides an electrostatic-discharge protection circuit, included in a semiconductor device, configured such that an impurity diffusion layer of a second conductivity type formed in a well of a first conductivity type and an impurity diffusion layer of the second conductivity type formed in a well of the second conductivity type are adjacent to each other interposing an element isolation region therebetween.

Specifically, an example semiconductor device is intended for a semiconductor device having a protected circuit and an electrostatic-discharge protection circuit configured to protect the protected circuit from electrostatic destruction; and the electrostatic-discharge protection circuit includes a first well of a first conductivity type and a second well of a second conductivity type formed in contact with each other in a semiconductor substrate, a first impurity diffusion layer of the first conductivity type and a third impurity diffusion layer of the second conductivity type formed apart from each other in the first well, a second impurity diffusion layer of the second conductivity type and a fourth impurity diffusion layer of the first conductivity type formed apart from each other in the second well, where the second and the third impurity diffusion layers are formed adjacent to each other interposing an element isolation region provided across a border between the first and the second wells, the third impurity diffusion layer is coupled to a first external connection terminal of the protected circuit, and the second and the fourth impurity diffusion layers are coupled to a second external connection terminal of the protected circuit.

In the example semiconductor device, the second and the third impurity diffusion layers are adjacent to each other interposing the element isolation region provided across the border between the first and the second wells, and have a same conductivity type. This enables the base resistance of the parasitic NPN transistor of the thyristor to be reduced without increasing the size of the thyristor. This allows the hold voltage of the thyristor to be increased, thus an electrostatic-discharge protection circuit having a high latch-up tolerance can be achieved.

In the example semiconductor device, the first impurity diffusion layer may be formed opposite the border between the first and the second wells across the third impurity diffusion layer, and the fourth impurity diffusion layer may be formed opposite the border between the first and the second wells across the second impurity diffusion layer.

In the example semiconductor device, the first impurity diffusion layer may include a first protrusion protruding toward the border between the first and the second wells, and the second impurity diffusion layer may include a second protrusion protruding opposite the border between the first and the second wells.

In this case, multiple ones of the third impurity diffusion layer may be formed spaced apart from each other in a direction parallel to the border between the first and the second wells, and the first protrusion may be formed in a region between a corresponding pair of the third impurity diffusion layers; and multiple ones of the fourth impurity diffusion layer may be formed spaced apart from each other in a direction parallel to the border between the first and the second wells, and the second protrusion may be formed in a region between a corresponding pair of the fourth impurity diffusion layers.

The example semiconductor device may be configured such that the first conductivity type is n-type, the second conductivity type is p-type, and a voltage of the first external connection terminal is higher than a voltage of the second external connection terminal.

In this case, the first external connection terminal may be a power supply terminal or an input/output terminal, and the second external connection terminal may be a ground terminal. Alternatively, the first external connection terminal may be a power supply terminal, and the second external connection terminal may be an input/output terminal.

In the example semiconductor device, the first impurity diffusion layer may be coupled to the first external connection terminal.

In this case, the electrostatic-discharge protection circuit may include a first trigger circuit, and a fifth impurity diffusion layer of the second conductivity type formed in the second well, where the first trigger circuit includes a trigger element whose first terminal is coupled to the first external connection terminal, and whose second terminal is coupled to the fifth impurity diffusion layer, and a resistive element coupled between the second terminal of the trigger element and the second external connection terminal.

In addition, the first trigger circuit may conduct electricity between the first external connection terminal and the base of a parasitic transistor in which the first well serves as the collector, the second well serves as the base, and the fourth impurity diffusion layer serves as the emitter at a voltage lower than a breakdown voltage of a parasitic transistor in which the second well serves as the collector, the first well serves as the base, and the third impurity diffusion layer serves as the emitter.

In the example semiconductor device, the electrostatic-discharge protection circuit may include a second trigger circuit, where the second trigger circuit includes a trigger element whose first terminal is coupled to the first impurity diffusion layer, and whose second terminal is coupled to the second and the fourth impurity diffusion layers, and a resistive element coupled between the first terminal of the trigger element and the first external connection terminal.

In this case, the second trigger circuit may conduct electricity between the second external connection terminal and the base of a parasitic transistor in which the second well serves as the collector, the first well serves as the base, and the third impurity diffusion layer serves as the emitter at a voltage lower than a breakdown voltage of a parasitic transistor in which the first well serves as the collector, the second well serves as the base, and the fourth impurity diffusion layer serves as the emitter.

In the example semiconductor device, the electrostatic-discharge protection circuit may include a third trigger circuit, where the third trigger circuit may be configured as a switch element whose first terminal is coupled to the first impurity diffusion layer, whose second terminal is coupled to the second and the fourth impurity diffusion layers, and whose third terminal is coupled to a power supply terminal.

In this case, when the power supply terminal is placed in a floating state, the third trigger circuit may conduct electricity between the second external connection terminal and the base of a parasitic transistor in which the second well serves as the collector, the first well serves as the base, and the third impurity diffusion layer serves as the emitter.

According to a semiconductor device of the present disclosure, a semiconductor device including an electrostatic-discharge protection circuit having a high latch-up tolerance and a small occupied area can be achieved.

### BRIEF DESCRIPTION OF THE DRAWINGS

FIGS. 1A-1B illustrate an electrostatic-discharge protection circuit according to the first embodiment; FIG. 1A is a top view, and FIG. 1B is a cross-sectional view taken along line Ib-Ib of FIG. 1A.

FIG. 2 is an equivalent circuit diagram illustrating an electrostatic-discharge protection circuit according to the first embodiment.

FIG. 3 is a graph showing a comparison between current-voltage characteristics of an electrostatic-discharge protection circuit according to the first embodiment and those of a conventional electrostatic-discharge protection circuit.

FIG. 4 is a graph showing a comparison of a relationship between the anode-to-cathode spacing and the hold voltage of an electrostatic-discharge protection circuit according to the first embodiment with that of a conventional electrostatic-discharge protection circuit.

FIGS. 5A-5B illustrate an example variation of the electrostatic-discharge protection circuit according to the first embodiment; FIG. 5A is a cross-sectional view, and FIG. 5B is an equivalent circuit diagram.

FIGS. 6A-6B are circuit diagrams illustrating examples of a trigger element used in the variation of the electrostatic-discharge protection circuit according to the first embodiment.

FIGS. 7A-7B illustrate another example variation of the electrostatic-discharge protection circuit according to the first embodiment; FIG. 7A is a cross-sectional view, and FIG. 7B is an equivalent circuit diagram.

FIGS. 8A-8B are circuit diagrams illustrating examples of a trigger element used in the another variation of the electrostatic-discharge protection circuit according to the first embodiment.

FIGS. 9A-9B illustrate still another example variation of the electrostatic-discharge protection circuit according to the first embodiment; FIG. 9A is a cross-sectional view, and FIG. 9B is an equivalent circuit diagram.

FIG. 10 is a circuit diagram illustrating an example of a trigger element used in the still another variation of the electrostatic-discharge protection circuit according to the first embodiment.

FIG. 11 is a top view of an electrostatic-discharge protection circuit according to the second embodiment.

FIGS. 12A-12D illustrate an electrostatic-discharge protection circuit according to the second embodiment of the present invention, and FIGS. 12A-12D are cross-sectional views respectively taken along line XIIa-XIIa, line XIIb-XIIb, line XIIc-XIIc, and line XIId-XIId of FIG. 11.

FIG. 13 is a cross-sectional view illustrating an electrostatic-discharge protection circuit according to a conventional example.

### DETAILED DESCRIPTION

### First Embodiment

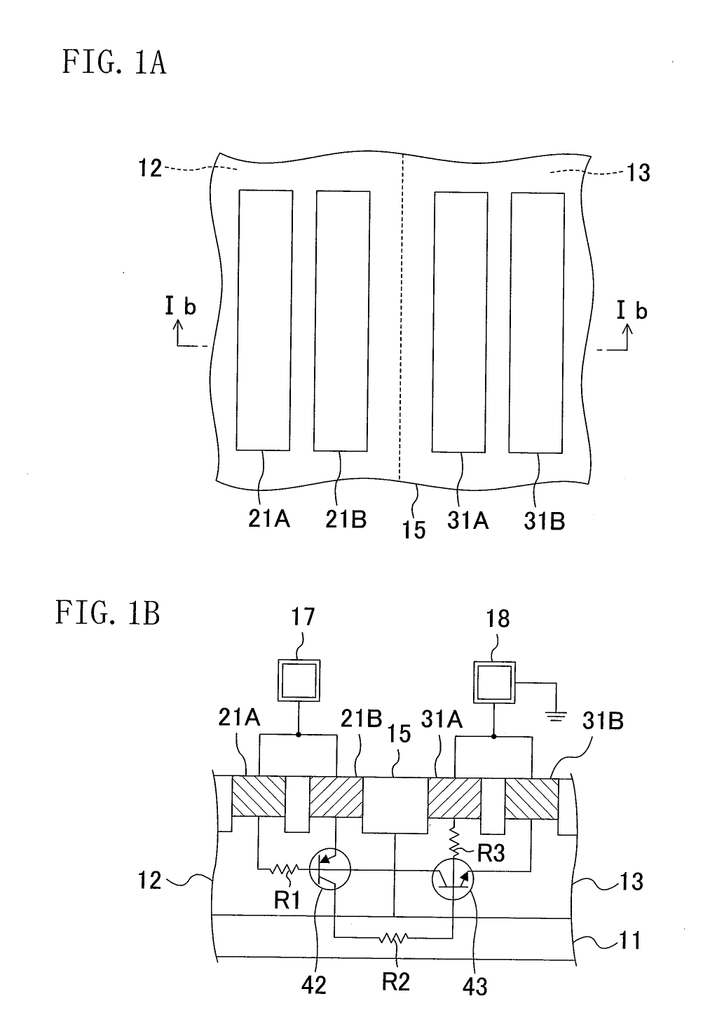

FIGS. 1A-1B illustrate an electrostatic-discharge (ESD) protection circuit included in a semiconductor device according to the first embodiment; FIG. 1A illustrates a planar configuration, and FIG. 1B illustrates a cross-sectional configuration taken along line Ib-Ib of FIG. 1A.

As shown in FIGS. 1A-1B, an ESD protection circuit according to the first embodiment is an ESD protection circuit of an SCR type. An n-type first well 12 and a p-type second well 13 are formed in contact with each other in a semiconductor substrate 11 such as a silicon substrate. An n-type first impurity diffusion layer 21A and a p-type third impurity diffusion layer 21B are formed in the first well 12. A p-type second impurity diffusion layer 31A and an n-type fourth impurity diffusion layer 31B are formed in the second well 13.

The first impurity diffusion layer 21A, the third impurity diffusion layer 21B, the second impurity diffusion layer 31A, and the fourth impurity diffusion layer 31B are spaced apart from each other by element isolation regions 15. The third impurity diffusion layer 21B and the second impurity diffusion layer 31A are formed adjacent to each other interposing the element isolation region 15 provided across the border between the first and the second wells 12 and 13. The first impurity diffusion layer 21A is formed opposite the border between the first and the second wells 12 and 13 across the third impurity diffusion layer 21B, and the fourth impurity diffusion layer 31B is formed opposite the border between the first and the second wells 12 and 13 across the second impurity diffusion layer 31A.

The first and the third impurity diffusion layers 21A and 21B are both connected to a first external connection terminal 17 of a protected circuit (not shown) formed in another region of the semiconductor substrate 11. The second and the fourth impurity diffusion layers 31A and 31B are both connected to a second external connection terminal 18 of the protected circuit. The first external connection terminal 17 is, for example, an input/output terminal, and the second external connection terminal 18 is, for example, a ground terminal.

In FIG. 1, an example is shown where the first external connection terminal 17 is an input/output terminal, and the second external connection terminal 18 is a ground terminal. However, any terminal combination may be used as long as the voltage of the first external connection terminal 17 is higher than the voltage of the second external connection terminal 18. For example, the first external connection terminal 17 may be either an input terminal or an output terminal which performs only one of input operation or output operation. Alternatively, the first external connection terminal 17 may be a power supply terminal, and the second external connection terminal 18 may be a ground terminal; or the first external connection terminal 17 may be a first power supply terminal, and the second external connection terminal 18 may be a second power supply terminal having a voltage lower than that of the first power supply terminal.

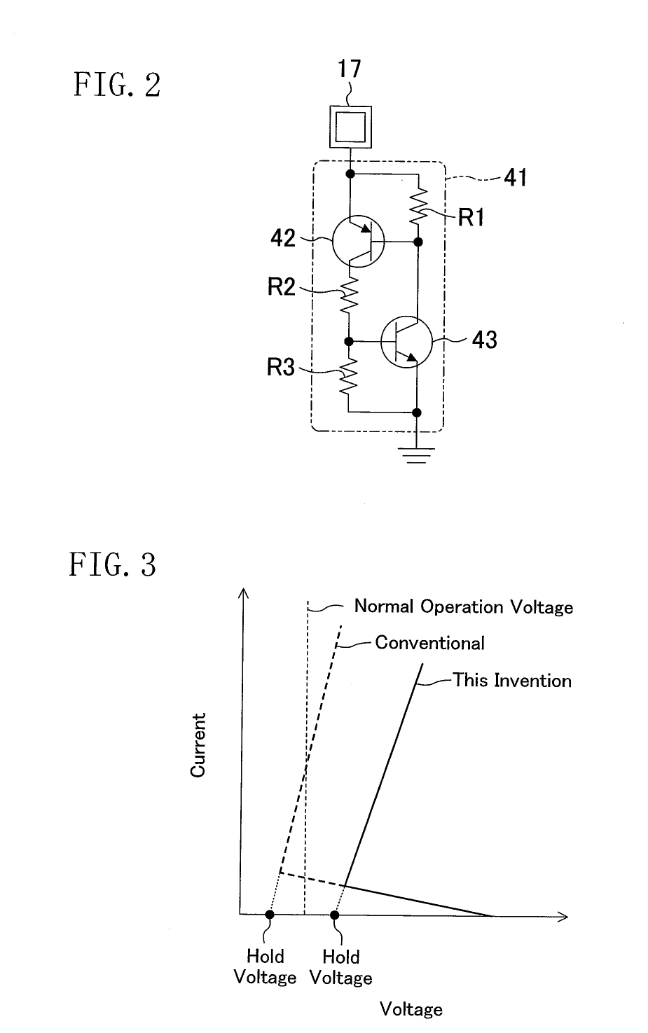

With such a configuration, as shown in FIG. 2, an ESD protection circuit in which a thyristor (SCR) 41 is connected between the first external connection terminal 17 of the protected circuit and the ground is formed. The thyristor 41 is equivalent to a parasitic PNP transistor 42 and a parasitic NPN transistor 43 whose bases and collectors are connected together. As shown in FIG. 1B, the parasitic PNP transistor 42 is formed such that the p-type third impurity diffusion layer 21B serves as the emitter, the n-type first well 12 serves as the base, and the p-type second well 13 serves as the collector. The parasitic NPN transistor 43 is formed such that the n-type fourth impurity diffusion layer 31B serves as the emitter, the p-type second well 13 serves as the base, and the n-type first well 12 serves as the collector.

If a surge is applied to the first external connection terminal 17, then the parasitic NPN transistor 43 goes into breakdown, and a collector current of the parasitic NPN transistor 43 flows through the n-type first well 12. This collector current and a resistive component R1 of the first well 12 cause a forward bias to be applied between the emitter and the base of the parasitic PNP transistor 42, thereby causing the parasitic PNP transistor 42 to conduct. The conduction of the parasitic PNP transistor 42 causes the collector current of the parasitic PNP transistor 42 to flow through the p-type second well 13. This collector current and resistive components R2 and R3 of the second well 13 increase the conductivity of the parasitic NPN transistor 43. Therefore, a positive feedback is created in the circuit, thereby establishing a low-impedance discharge path between the third impurity diffusion layer 21B, which serves as an anode of the thyristor, and the fourth impurity diffusion layer 31 B, which serves as a cathode of the thyristor. Since this allows the surge current to be conducted to the second external connection terminal, which is a ground terminal, the protected circuit can be protected.

In order to increase the hold voltage of the thyristor 41, reducing the base resistance of the parasitic NPN transistor 43 to reduce the conductivity of the parasitic NPN transistor 43 is effective. The base resistance of the parasitic NPN transistor 43 is dependent on the values of resistive components R2 and R3 shown in FIG. 2.

If conditions such as impurity concentration are the same, the value of resistive component R2 decreases as the distance between the border between the first and the second wells 12 and 13 and the second impurity diffusion layer 31A decreases. The value of resistive component R3 decreases as the area of the second impurity diffusion layer 31A increases.

Meanwhile, the current capability of the thyristor 41 increases as the spacing between the anode, which is the emitter of the parasitic PNP transistor 42, and the cathode, which is the emitter of the parasitic NPN transistor 43, decreases. That is, from a viewpoint of current capability, it is preferable to reduce the spacing between the third impurity diffusion layer 21B and the fourth impurity diffusion layer 31B.

In conventional thyristors, importance is given to current capability, and a p-type impurity diffusion layer in an n-type well is formed on the side of the border between the n-type well and a p-type well, and an n-type impurity diffusion layer in a p-type well is formed on the side of the border between the n-type well and the p-type well. That is, the p-type impurity diffusion layer in the n-type well and the n-type impurity diffusion layer in the p-type well are formed adjacent to each other across the border between the n-type well and the p-type well.

In this case, one possible approach is to increase the hold voltage by increasing the area of the p-type impurity diffusion layer in the p-type well to reduce the value of the resistive component R3. However, due to a limitation on the size of a thyristor, an effect of reducing the value of the resistive component R3 is limited. In addition, since a contribution of the value of the resistive component R2 is large, the amount of base resistance of the parasitic NPN transistor cannot be significantly reduced.

An ESD protection circuit according to the first embodiment is configured such that the p-type second impurity diffusion layer 31A is adjacent to the p-type third impurity diffusion layer 21B interposing the element isolation region 15 provided across the border between the first and the second wells 12 and 13. That is, of both the n-type first impurity diffusion layer 21A and the p-type third impurity diffusion layer 21B formed in the first well 12, the p-type third impurity diffusion layer 21B is formed at a location closer to the border between the first and the second wells 12 and 13; and of both the p-type second impurity diffusion layer 31A and the n-type fourth impurity diffusion layer 31B formed in the second well 13, the p-type second impurity diffusion layer 31A is formed at a location closer to the border between the first and the second wells 12 and 13. Therefore, the value of the resistive component R2, which serves as the base resistance of the parasitic NPN transistor 43, can be made smaller than that of a conventional thyristor in which a p-type impurity diffusion layer in an n-type well and an n-type impurity diffusion layer in a p-type well are adjacent to each other. Accordingly, as shown in FIG. 3, the hold voltage can be higher than a normal operation voltage of a semiconductor device, and thus latch-up can be prevented from occurring.

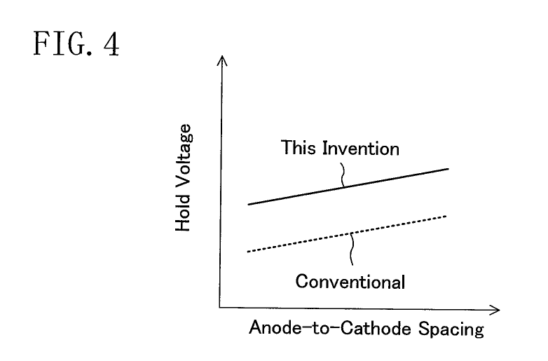

FIG. 4 shows relationships between the anode-to-cathode spacings and the hold voltages. An increase of an anode-to-cathode spacing causes the amplification factor to decrease, therefore a hold voltage can be increased. Also in a conventional thyristor in which a p-type impurity diffusion layer in an n-type well and an n-type impurity diffusion layer in a p-type well are adjacent to each other, an increase of the spacing between the p-type impurity diffusion layer in the n-type well, which serves as an anode, and the n-type impurity diffusion layer in the p-type well, which serves as a cathode, causes the hold voltage to increase. However, in such a case, the distance from the border between the n-type and the p-type wells to the p-type impurity diffusion layer in the p-type well also increases. Since this causes the value of the resistive component R2 to increase, the effect to increase the hold voltage is small. In addition, the size of a thyristor becomes large.

On the contrary, in this embodiment, the second impurity diffusion layer 31A is formed at a location closer to the border between the first and the second wells 12 and 13 than the fourth impurity diffusion layer 31B. Therefore, even if the spacing between the third impurity diffusion layer 21B, which serves as an anode, and the fourth impurity diffusion layer 31B, which serves as a cathode, is increased, there is little increase in the value of the resistive component R2. In addition, since a contribution of the resistive component R2 to the hold voltage is large, a hold voltage significantly higher than that of a conventional thyristor can be achieved even if the anode-to-cathode spacing is small. That is, an ESD protection circuit of this embodiment enables to achieve a small-sized ESD protection circuit in which latch-up is less likely to occur.

An ESD protection circuit of this embodiment may include a trigger circuit which reduces the snap-back voltage at which the thyristor turns on. Providing a trigger circuit allows the turn-on voltage to be reduced without reducing the hold voltage of the thyristor.

The trigger circuit can be, for example, a circuit which conducts electricity between the base of the parasitic NPN transistor 43 and the first external connection terminal 17 at a voltage lower than a breakdown voltage of the parasitic PNP transistor 42.

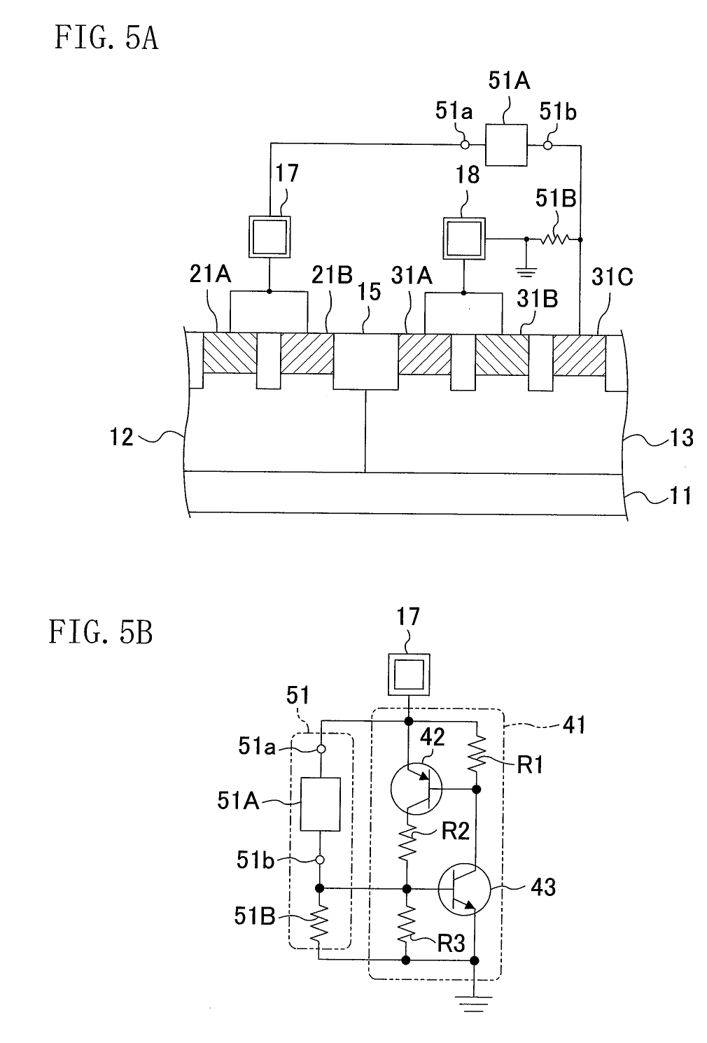

A concrete example is shown in FIGS. 5A-5B. FIG. 5A illustrates a cross-sectional configuration of an ESD protection circuit connecting a first trigger circuit 51, and FIG. 5B illustrates a circuit configuration of the ESD protection circuit. The first trigger circuit 51 includes a trigger element 51A and a resistive element 51B for voltage regulation. A first terminal 51a of the trigger element 51A is connected to the first external connection terminal 17; and a second terminal 51b is connected to a p-type fifth impurity diffusion layer 31C formed in the p-type second well 13, and is also connected to a second external connection terminal 18 through the resistive element 51B. The fifth impurity diffusion layer 31C is formed opposite the border between the first and the second wells 12 and 13 across the second and the fourth impurity diffusion layers 31A and 31B.

That is, the trigger element 51A is connected between the first external connection terminal 17 and the second well 13, which serves as the base of the parasitic NPN transistor 43. The trigger element 51A goes to an “on” state at a voltage lower than the parasitic PNP transistor 42. Therefore, when a surge is applied to the first external connection terminal 17, the trigger element 51A conducts prior to the thyristor 41. When the trigger element 51A conducts, a current flows through the resistive element 51B, thereby causing the base of the parasitic NPN transistor 43 to float with respect to a ground level due to a current-resistance (IR) drop. This causes a forward bias to be applied between the base and the emitter of the parasitic NPN transistor 43, thereby causing the parasitic NPN transistor 43 to conduct. After the conduction of the parasitic NPN transistor 43, the surge current is conducted to ground as in the case where the first trigger circuit 51 is not provided.

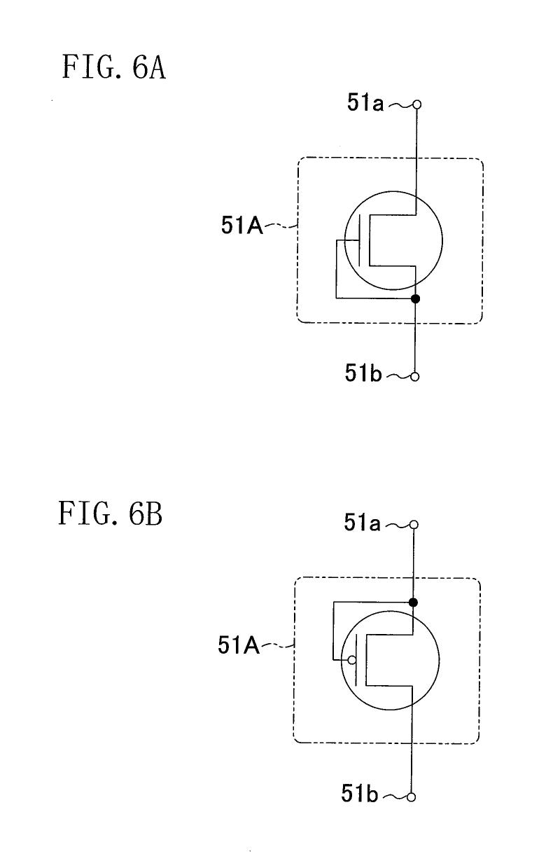

The trigger element MA can be achieved using, for example, a MOS (metal-oxide-semiconductor) transistor as shown in FIGS. 6A and 6B. If an n-type MOS transistor is used, the gate electrode is connected to the second terminal 51b as shown in FIG. 6A, while if a p-type MOS transistor is used, the gate electrode is connected to the first terminal 51a as shown in FIG. 6B. The voltage at which the thyristor 41 turns on by the first trigger circuit 51 can be set using a threshold of the trigger element 51A, which is a MOS transistor, and the value of the resistive element 51B.

The trigger circuit may be a circuit which conducts electricity between the base of the parasitic PNP transistor 42 and the ground at a voltage lower than a breakdown voltage of the parasitic NPN transistor 43.

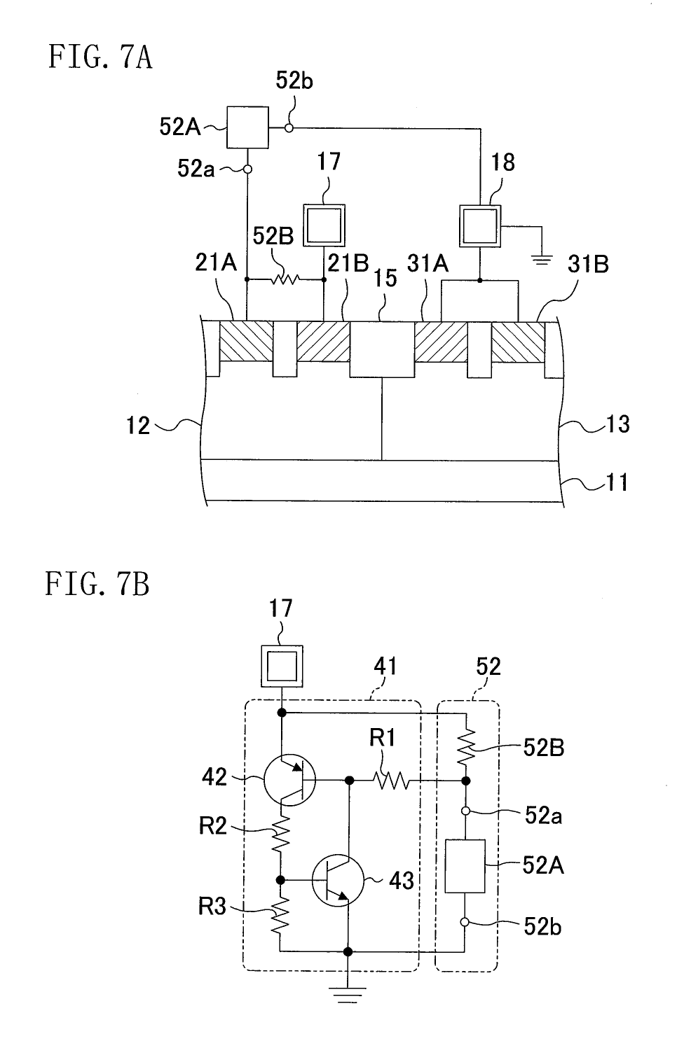

A concrete example for such a case is shown in FIGS. 7A-7B. FIG. 7A illustrates a cross-sectional configuration of an ESD protection circuit, and FIG. 7B illustrates a circuit configuration of the ESD protection circuit. A second trigger circuit 52 includes a trigger element 52A and a resistive element 52B for voltage regulation. A first terminal 52a of the trigger element 52A is connected to the n-type first impurity diffusion layer 21A formed in the n-type first well 12, and a second terminal 52b is connected to the second external connection terminal 18. In addition, the first terminal 52a of the trigger element 52A is connected to the first external connection terminal 17 through the resistive element 52B.

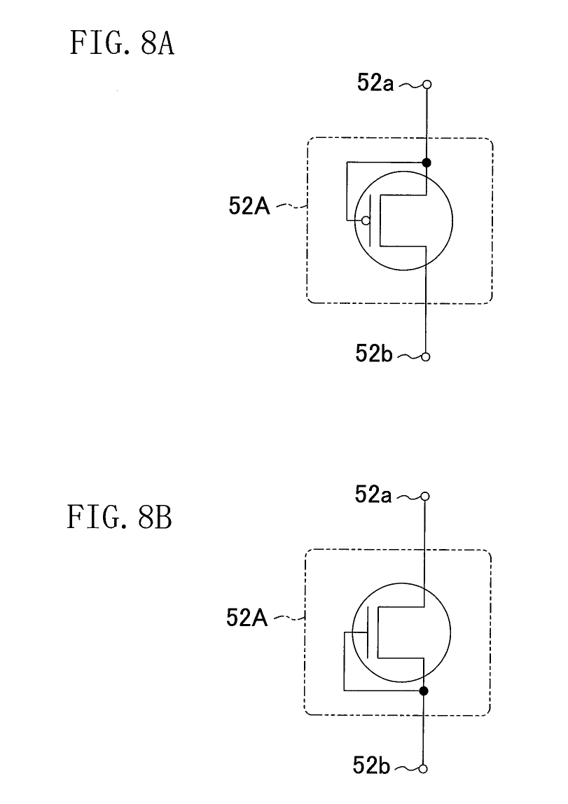

That is, the trigger element 52A is connected between the first well 12, which serves as the base of the parasitic PNP transistor 42 and the ground. The trigger element 52A goes to an “on” state at a voltage lower than the parasitic NPN transistor 43. Therefore, when a surge is applied to the first external connection terminal 17, the trigger element 52A conducts prior to the thyristor 41. When the trigger element 52A conducts, a current flows through the resistive element 52B, thereby causing a forward bias to be applied between the base and the emitter of the parasitic PNP transistor 42 due to a current-resistance (IR) drop. This causes the parasitic PNP transistor 42 to conduct. The conduction of the parasitic PNP transistor 42 causes the parasitic NPN transistor 43 to conduct, and thus the surge current is conducted to ground as in the case where the second trigger circuit 52 is not provided. Also in this case, the trigger element 52A can be a MOS transistor as shown in FIGS. 8A and 8B. If a p-type MOS transistor is used, the gate electrode is connected to the first terminal 52a as shown in FIG. 8A, while if an n-type MOS transistor is used, the gate electrode is connected to the second terminal 52b as shown in FIG. 8B.

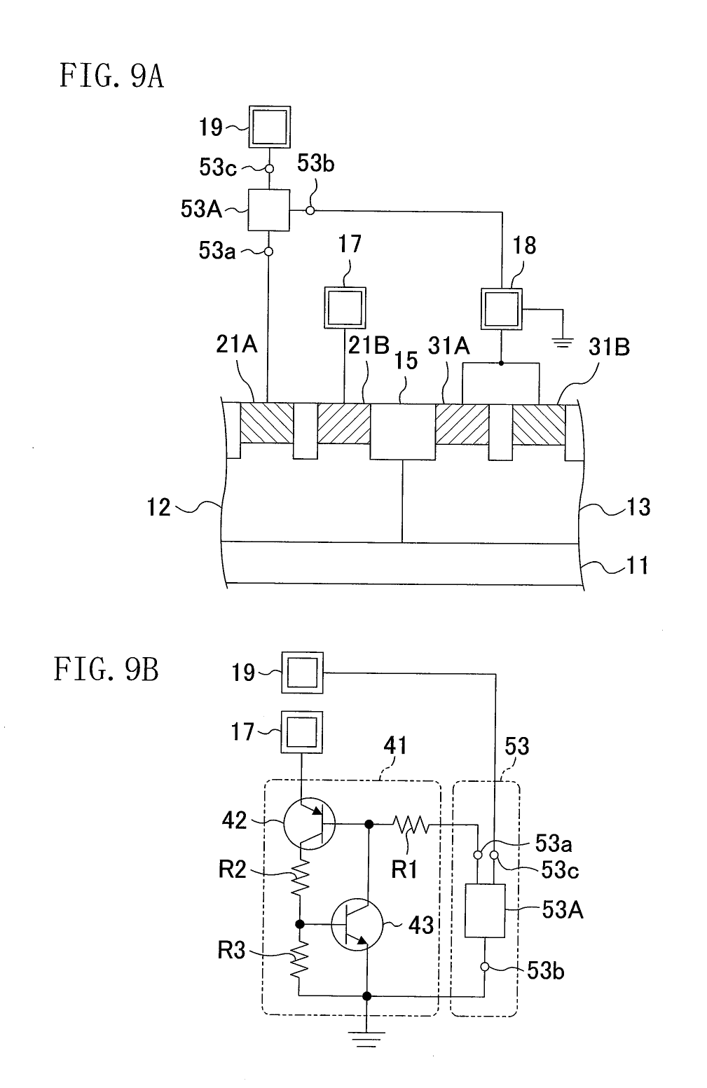

In addition, if the first external connection terminal 17 is an input/output terminal of the protected circuit, the trigger circuit may be configured to trigger using the characteristic of the power supply terminal being placed in a floating state upon an application of a surge. A specific configuration in this case can be the one shown in FIGS. 9A-9B. FIG. 9A illustrates a cross-sectional configuration of an ESD protection circuit, and FIG. 9B illustrates a circuit configuration of the ESD protection circuit. A third trigger circuit 53 includes a trigger element 53A. A first terminal 53a of the trigger element 53A is connected to the first impurity diffusion layer 21A, and a second terminal 53b is connected to the second external connection terminal 18 and is grounded. A third terminal 53c is connected to a power supply terminal 19. In the trigger element 53A, electricity is conducted between the first terminal 53a and the second terminal 53b when the third terminal 53c is placed in a floating state.

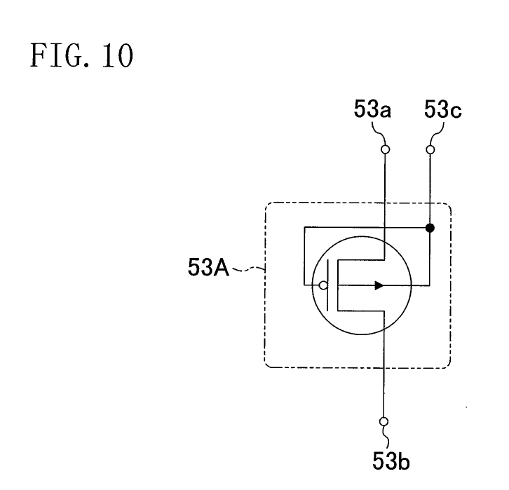

Normally, since a supply voltage is applied to the power supply terminal 19, the trigger element 53A is in an “off' state. However, in a floating state where no supply voltage is applied to the power supply terminal 19, the trigger element 53A is in an “on” state. Accordingly, if a surge is applied to the first external connection terminal 17 while the power supply terminal 19 is in a floating state, then the trigger element 53A in an “on” state conducts electricity, and thus a forward bias is applied between the base and the emitter of the parasitic PNP transistor 42, thereby causing the parasitic PNP transistor 42 to conduct. The conduction of the parasitic PNP transistor 42 causes the parasitic NPN transistor 43 to conduct, and thus the surge current is conducted to ground as in the case where the third trigger circuit 53 is not provided. In this case, the trigger element 53A can be a MOS transistor as shown in FIG. 10. If a p-type MOS transistor is used, the gate electrode and a substrate region are connected to the power supply terminal 19 as shown in FIG. 10.

In the first embodiment, an example has been described assuming that the first and the fourth impurity diffusion layers 21A and 31B are of n-type, and the second and the third impurity diffusion layers 31A and 21B are of p-type. However, the first and the fourth impurity diffusion layers 21A and 31B may be of p-type, and the second and the third impurity diffusion layers 31A and 21B may be of n-type.

Although examples have been presented in which the first and the second trigger circuits 51 and 52 are each formed by a MOS transistor and a resistive element, and an example has been presented in which the third trigger circuit 53 is formed by a MOS transistor, any circuit may be used as long as electricity is conducted at a predetermined voltage. For example, a diode etc. may be used instead of a MOS transistor.

### Second Embodiment

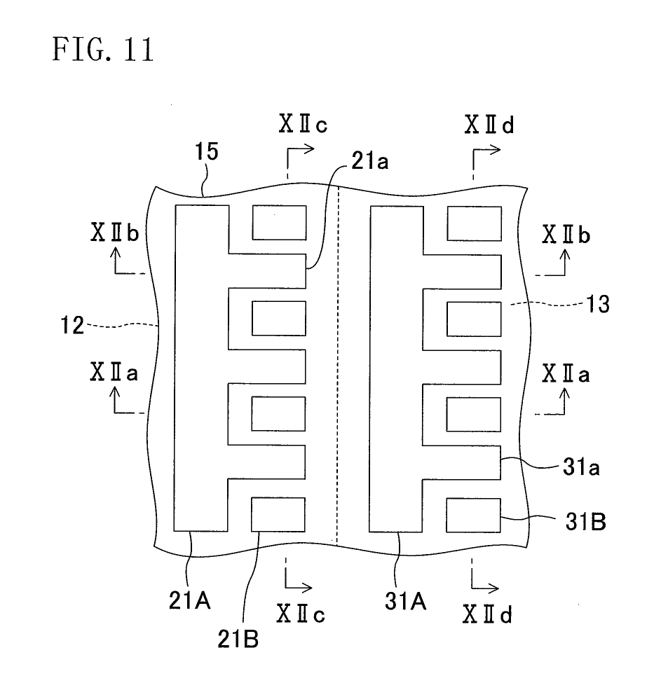

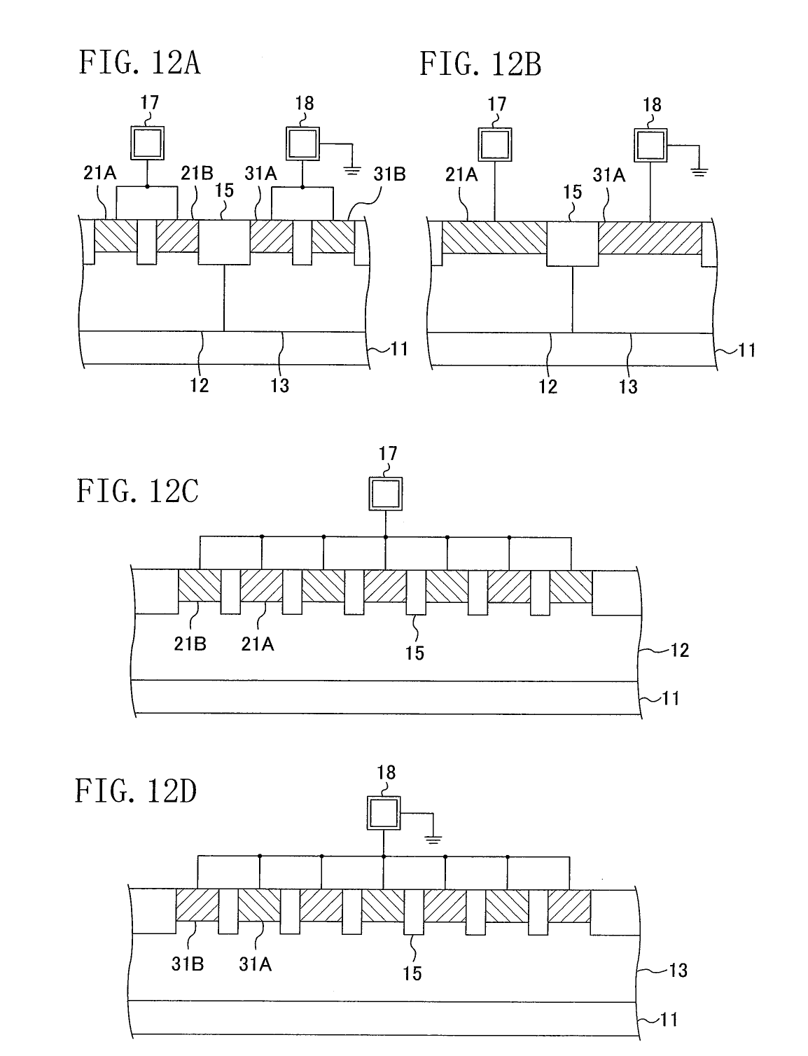

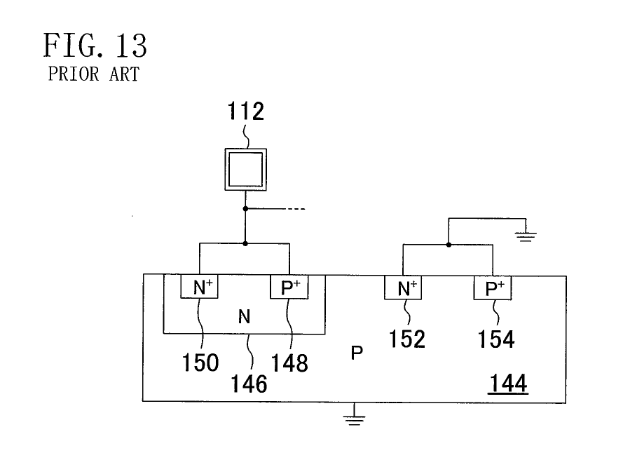

The second embodiment will be described below with reference to the drawings. FIGS. 11 and 12A-12D illustrate an ESD protection circuit according to the second embodiment; FIG. 11 illustrates a planar configuration, and FIGS. 12A-12D illustrate cross-sectional configurations respectively taken along line XIIa-XIIa, line XIIb-XIIb, line XIIc-XIIc, and line XIId-XIId of FIG. 11. In FIGS. 11 and 12A-12D, the same reference characters as those in FIG. 1 indicate the same or similar components, and the explanation thereof will be omitted.

As shown in FIGS. 11 and 12A-12D, an ESD protection circuit according to the second embodiment is an ESD protection circuit of an SCR type. A first impurity diffusion layer 21A formed in an n-type first well 12 includes first protrusions 21a protruding toward the border between the first and the second wells 12 and 13. A second impurity diffusion layer 31A includes second protrusions 31a protruding opposite the border between the first and the second wells 12 and 13. A plurality of third impurity diffusion layers 21B and a plurality of fourth impurity diffusion layers 31B are formed spaced apart from each other, respectively; the first protrusions 21a are each formed in a region between a corresponding pair of the third impurity diffusion layers 21B, and the second protrusions 31a are each formed in a region between a corresponding pair of the fourth impurity diffusion layers 31B.

With such a configuration, the effective well resistances of the first and the second wells 12 and 13 become small. This further reduces the base resistances of the parasitic PNP transistor 42 and the parasitic NPN transistor 43, thereby allowing the hold voltage to increase. Therefore, an ESD protection circuit in which latch-up is even less likely to occur can be achieved.

In the ESD protection circuit of this embodiment, the third impurity diffusion layer 21B, which serves as an anode of the thyristor 41, and the fourth impurity diffusion layer 31B, which serves as a cathode, have areas smaller than those of the ESD protection circuit of the first embodiment. This causes the current capability to be lower than that of the ESD protection circuit of the first embodiment. However, the current capability is normally large enough to transfer the surge, thereby causing no problems.

Note that although an example has been presented in which a plurality of the first protrusions 21a and a plurality of the second protrusions 31a are formed, the numbers of the first and the second protrusions 21a and 31a may be only one each. In such a case, the numbers of the third and the fourth impurity diffusion layers 21B and 31B may be one each.

An ESD protection circuit of the second embodiment may also include a trigger circuit similarly to the ESD protection circuit of the first embodiment. This allows the snap-back voltage to be reduced without any change of the hold voltage.

In the second embodiment, an example has been described assuming that the first and the fourth impurity diffusion layers 21A and 31B are of n-type, and the second and the third impurity diffusion layers 31A and 21B are of p-type. However, the first and the fourth impurity diffusion layers 21A and 31B may be of p-type, and the second and the third impurity diffusion layers 31A and 21B may be of n-type. In such a case, this can be achieved by forming third protrusions protruding opposite the border between the first and the second wells 12 and 13 in the third impurity diffusion layer 21B, and by forming fourth protrusions protruding towards the border between the first and the second wells 12 and 13 in the fourth impurity diffusion layer 31B.

The semiconductor device according to the present disclosure achieves an electrostatic-discharge protection circuit having a high latch-up tolerance and a small occupied area, and is useful as a semiconductor device having an electrostatic-discharge protection circuit which protects a protected circuit from electrostatic destruction etc.

What is claimed is:

1. A semiconductor device, comprising:
a protected circuit; and
an electrostatic-discharge protection circuit configured to protect the protected circuit from electrostatic destruction,
wherein
the electrostatic-discharge protection circuit includes
a first well of a first conductivity type and a second well of a second conductivity type formed in contact with each other in a semiconductor substrate,
a first impurity diffusion layer of the first conductivity type and a third impurity diffusion layer of the second conductivity type formed apart from each other in the first well,
a second impurity diffusion layer of the second conductivity type and a fourth impurity diffusion layer of the first conductivity type formed apart from each other in the second well,
the second and the third impurity diffusion layers are formed adjacent to each other interposing an element isolation region provided across a border between the first and the second wells,
the third impurity diffusion layer is coupled to a first external connection terminal of the protected circuit, and
the second and the fourth impurity diffusion layers are coupled to a second external connection terminal of the protected circuit.

2. The semiconductor device of claim 1, wherein
the first impurity diffusion layer is formed opposite the border between the first and the second wells across the third impurity diffusion layer, and
the fourth impurity diffusion layer is formed opposite the border between the first and the second wells across the second impurity diffusion layer.

3. The semiconductor device of claim 1, wherein
the first impurity diffusion layer includes a first protrusion protruding toward the border between the first and the second wells, and
the second impurity diffusion layer includes a second protrusion protruding opposite the border between the first and the second wells.

4. The semiconductor device of claim 3, wherein
multiple ones of the third impurity diffusion layer are formed spaced apart from each other in a direction parallel to the border between the first and the second wells, and
the first protrusion is formed in a region between a corresponding pair of the third impurity diffusion layers, and
multiple ones of the fourth impurity diffusion layer are formed spaced apart from each other in a direction parallel to the border between the first and the second wells, and
the second protrusion is formed in a region between a corresponding pair of the fourth impurity diffusion layers.

5. The semiconductor device of claim 1, wherein
the first conductivity type is n-type,
the second conductivity type is p-type, and
a voltage of the first external connection terminal is higher than a voltage of the second external connection terminal.

6. The semiconductor device of claim 5, wherein
the first external connection terminal is a power supply terminal or an input/output terminal, and
the second external connection terminal is a ground terminal.

7. The semiconductor device of claim 5, wherein
the first external connection terminal is a power supply terminal, and
the second external connection terminal is an input/output terminal.

8. The semiconductor device of claim 1, wherein
the first impurity diffusion layer is coupled to the first external connection terminal.

9. The semiconductor device of claim 8, wherein
the electrostatic-discharge protection circuit includes a first trigger circuit, and a fifth impurity diffusion layer of the second conductivity type formed in the second well, and
the first trigger circuit includes
a trigger element whose first terminal is coupled to the first external connection terminal, and whose second terminal is coupled to the fifth impurity diffusion layer, and
a resistive element coupled between the second terminal of the trigger element and the second external connection terminal.

10. The semiconductor device of claim 9, wherein
the first trigger circuit conducts electricity between the first external connection terminal and the base of a parasitic transistor in which the first well serves as the collector, the second well serves as the base, and the fourth impurity diffusion layer serves as the emitter at a voltage lower than a breakdown voltage of a parasitic transistor in which the second well serves as the collector, the first well serves as the base, and the third impurity diffusion layer serves as the emitter.

11. The semiconductor device of claim 1, wherein
the electrostatic-discharge protection circuit includes a second trigger circuit, and
the second trigger circuit includes
a trigger element whose first terminal is coupled to the first impurity diffusion layer, and whose second terminal is coupled to the second and the fourth impurity diffusion layers, and
a resistive element coupled between the first terminal of the trigger element and the first external connection terminal.

12. The semiconductor device of claim 11, wherein
the second trigger circuit conducts electricity between the second external connection terminal and the base of a parasitic transistor in which the second well serves as the collector, the first well serves as the base, and the third impurity diffusion layer serves as the emitter at a voltage lower than a breakdown voltage of a parasitic transistor in which the first well serves as the collector, the second well serves as the base, and the fourth impurity diffusion layer serves as the emitter.

13. The semiconductor device of claim 1, wherein
the electrostatic-discharge protection circuit includes a third trigger circuit, and
the third trigger circuit is a switch element whose first terminal is coupled to the first impurity diffusion layer, whose second terminal is coupled to the second and the fourth impurity diffusion layers, and whose third terminal is coupled to a power supply terminal.

14. The semiconductor device of claim 13, wherein
when the power supply terminal is placed in a floating state, the third trigger circuit conducts electricity between the second external connection terminal and the base of a parasitic transistor in which the second well serves as the collector, the first well serves as the base, and the third impurity diffusion layer serves as the emitter.
